(19) United States
(12) Patent Application Publication
(10) Pub. No.: US 2025/0372790 A1
(43) Pub. Date: Dec. 4, 2025

(54) BATTERY EXCHANGE SYSTEM

(71) Applicant: NEC Corporation, Tokyo (JP)

(72) Inventor: Atsushi NAGATA, Tokyo (JP)

(73) Assignee: NEC Corporation, Tokyo (JP)

(21) Appl. No.: 19/204,724

(22) Filed: May 12, 2025

(30) Foreign Application Priority Data
Jun. 3, 2024 (JP) 2024-089612

(51) Int. Cl. H01M 50/244; H01M 50/216; H01M 50/284; H01M 50/298; H05K 7/14

(52) U.S. Cl. CPC H01M 50/244; H01M 50/216; H01M 50/284; H01M 50/298; H05K 7/1487; H01M 2220/10

(57) ABSTRACT

A battery exchange system according to an aspect of the present disclosure includes: a dummy battery part including a positive electrode and a negative electrode, the dummy battery part being attachable to a circuit board battery holder of a circuit board of an electronic device, the circuit board battery holder being a battery holder for a button-type battery, of a circuit board of an electronic device; and a battery board including a battery board battery holder that is a battery holder for a button-type battery including a positive terminal connected to the positive electrode and a negative terminal connected to the negative electrode, the battery board being disposed in the electronic device so as to be insertable and removable from an outside of a housing of the electronic device.

This application is based upon and claims the benefit of priority from Japanese Patent Application No. 2024-089612, filed on Jun. 3, 2024, the disclosure of which is incorporated herein in its entirety by reference.

### TECHNICAL FIELD

The present disclosure relates to a battery exchange system.

### BACKGROUND ART

JP 9-63555 A discloses a battery holder mechanism including a dummy battery and a second battery holder. The dummy battery includes positive and negative electrode plates insulated from each other. The dummy battery has a shape conforming to a first battery holder to which a data holding battery is attached. The first battery holder is attached to a circuit board built in the electronic device. The second battery holder includes positive and negative electrode terminals connected to positive and negative electrode plates of the dummy battery, and a holder portion to which the battery is detachably attached. The battery holder mechanism is attached to a housing of the electronic device.

### SUMMARY

An object of the present disclosure is to provide a battery exchange system capable of reducing an area used on a surface of a housing by a system that enables exchange of a coin battery without opening the housing of an electronic device.

A battery exchange system according to an aspect of the present disclosure includes: a dummy battery part including a positive electrode and a negative electrode, the dummy battery part being attachable to a circuit board battery holder of a circuit board of an electronic device, the circuit board battery holder being a battery holder for a button-type battery, of a circuit board of an electronic device; and a battery board including a battery board battery holder that is a battery holder for a button-type battery including a positive terminal connected to the positive electrode and a negative terminal connected to the negative electrode, the battery board being disposed in the electronic device so as to be insertable and removable from an outside of a housing of the electronic device.

### BRIEF DESCRIPTION OF THE DRAWINGS

Exemplary features and advantages of the present disclosure will become apparent from the following detailed description when taken with the accompanying drawings in which:

FIG. 1 is a diagram schematically illustrating an example of a configuration of a battery exchange system according to the present disclosure;

FIG. 2 is a diagram illustrating an example of a configuration of the battery exchange system according to the present disclosure;

FIG. 3 is a diagram schematically illustrating an example of a configuration of the battery exchange system according to the present disclosure;

FIG. 4 is a diagram schematically illustrating an example of a bracket portion 210 of an extension board according to the present disclosure;

FIG. 5 is a diagram schematically illustrating an example of a bracket portion and a lid portion of the extension board according to the present disclosure;

FIG. 6 is a diagram schematically illustrating an example of a configuration of an electronic device according to the present disclosure;

FIG. 7 is a diagram illustrating an inside of a housing of the electronic device according to the present disclosure;

FIG. 8 is a diagram illustrating an example of a configuration of a battery exchange system according to the present disclosure;

FIG. 9 is a diagram schematically illustrating an example of a bracket portion of an extension board according to the present disclosure;

FIG. 10 is a diagram schematically illustrating an example of a bracket portion and a lid portion of the extension board according to the present disclosure;

FIG. 11 is a diagram illustrating an example of a configuration of a battery exchange system according to the present disclosure;

FIG. 12 is a second diagram illustrating an example of a configuration of a battery exchange system according to the present disclosure;

FIG. 13 is a diagram illustrating an example of a configuration of a battery exchange system according to the present disclosure;

FIG. 14 is a diagram illustrating an example of a configuration of a battery exchange system according to the present disclosure;

FIG. 15 is a diagram illustrating an example of a configuration of a battery exchange system according to the present disclosure; and

FIG. 16 is a diagram schematically illustrating an example of a battery exchange system according to the present disclosure.

### EXAMPLE EMBODIMENT

Next, example embodiments of the present disclosure will be described in detail with reference to the drawings.

### First Example Embodiment

First, a first example embodiment of the present disclosure will be described in detail with reference to the drawings.

### <Configuration>

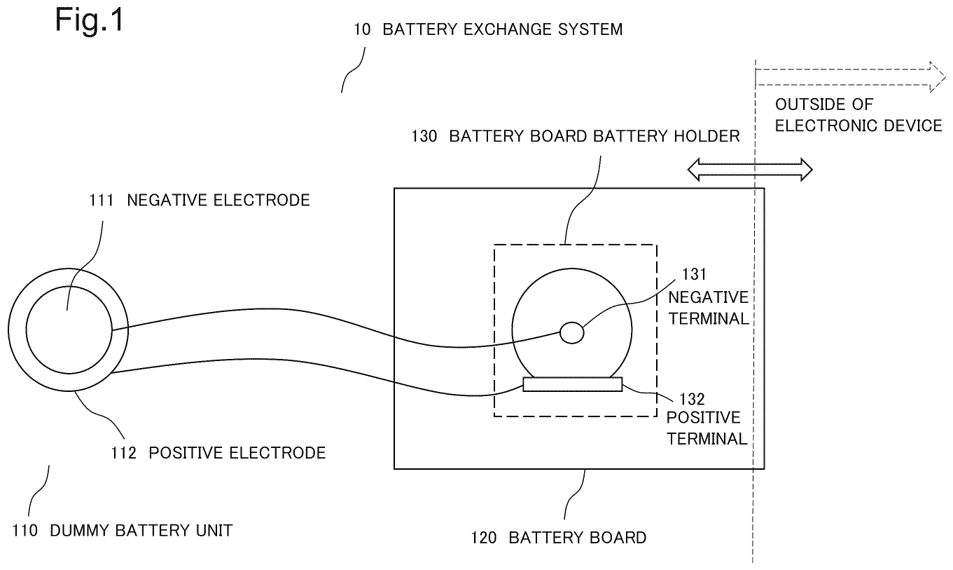

FIG. 1 is a diagram schematically illustrating an example of a configuration of a battery exchange system according to the present disclosure.

Hereinafter, a battery exchange system according to the first example embodiment of the present disclosure will be described in detail with reference to FIG. 1.

In the example illustrated in FIG. 1, a battery exchange system 10 according to the first example embodiment of the present disclosure includes a dummy battery unit 110 and a battery board 120.

The dummy battery unit 110 includes a positive electrode 112 and a negative electrode 111 that can be attached to a circuit board battery holder, which is a battery holder for a button-type battery, of a circuit board of an electronic device.

The battery board 120 includes a battery board battery holder 130 that is a battery holder for a button-type battery including a positive terminal 132 connected to the positive electrode 112 and a negative terminal 131 connected to the negative electrode 111, and is disposed in the electronic device so as to be insertable to and removable from the outside of a housing of the electronic device.

FIG. 1 is a diagram schematically illustrating the battery exchange system 10. The shapes of the battery board 120, the battery board battery holder 130, the negative terminal 131, the positive terminal 132, and the like may be different from those of the example illustrated in FIG. 1. In addition, another diagram illustrating the battery exchange system according to the present disclosure is a diagram schematically illustrating the battery exchange system according to the present disclosure. Another diagram showing the electronic device according to the present disclosure is a diagram schematically showing the electronic device according to the present disclosure. The shape of the member according to the present disclosure depicted in these diagrams may be different from the shape of the member depicted in the diagrams.

As described above, the button-type battery is also referred to as a coin-type battery, a coin battery, or the like. The dummy battery unit 110 has a shape that can be attached to a battery holder of a circuit board of an electronic device. The shape of the dummy battery unit 110 is a shape in which, when the dummy battery unit 110 is attached to the battery holder of the circuit board of the electronic device, the negative electrode 111 and the positive electrode 112 are not short-circuited, the positive terminal of the battery holder of the circuit board of the electronic device is in contact with the positive electrode 112, and the negative terminal of the battery holder of the circuit board of the electronic device is in contact with the negative electrode 111. The shape of the dummy battery unit 110 may be the same as the shape of the button-type battery mounted on the battery holder of the circuit board of the electronic device. The shape of the dummy battery unit 110 may be different from the shape of the button-type battery mounted on the battery holder of the circuit board of the electronic device.

The battery board battery holder 130 is configured to be fixed to the battery board battery holder 130 such that when a button-type battery that can be attached to the battery board battery holder 130 is attached to the battery board battery holder 130, the button-type battery is detachable from the battery board battery holder 130. In addition, the battery board battery holder 130 is configured such that when a button-type battery that can be attached to the battery board battery holder 130 is attached to the battery board battery holder 130, a positive electrode of the button-type battery is in contact with the positive terminal 132, and a negative electrode of the button-type battery is in contact with the negative terminal 131. In addition, the battery board battery holder 130 is configured so that the positive terminal 132 and the negative terminal 131 are not short-circuited when a button-type battery that can be attached to the battery board battery holder 130 is attached to the battery board battery holder 130.

The negative electrode 111 of the dummy battery unit 110 is connected to the negative terminal 131 of the battery board battery holder 130 by, for example, a cable or the like so as to be electrically connected to the negative terminal 131 of the battery board battery holder 130. The positive electrode 112 of the dummy battery unit 110 is connected to the positive terminal 132 of the battery board battery holder 130 by, for example, a cable or the like so as to be electrically connected to the positive terminal 132 of the battery board battery holder 130. In the example illustrated in FIG. 1, a cable connecting the negative electrode 111 and the negative terminal 131 and a cable connecting the positive electrode 112 and the positive terminal 132 are drawn independently. However, the cable connecting the negative electrode 111 and the negative terminal 131 and the cable connecting the positive electrode 112 and the positive terminal 132 may be combined. Specifically, for example, a coating of a part of the cable connecting the negative electrode 111 and the negative terminal 131 and a coating of a part of the cable connecting the positive electrode 112 and the positive terminal 132 may be bonded. The cable connecting the negative electrode 111 and the negative terminal 131 and the cable connecting the positive electrode 112 and the positive terminal 132 are insulated from each other by a coating.

The length of the cable connecting the negative electrode 111 and the negative terminal 131 and the length of the cable connecting the positive electrode 112 and the positive terminal 132 are lengths that allow the battery board 120 to be pulled out from the housing of the electronic device such that at least a part of the battery board battery holder 130 is exposed from the housing of the electronic device. In this case, at least a part of the battery board battery holder 130 is in a range in which the battery mounted on the battery board battery holder 130 can be exchanged from the outside of the housing of the electronic device when at least a part of the battery board battery holder 130 is exposed from the housing of the electronic device. The length of these cables may be a length that allows the battery board 120 to be pulled out from the housing of the electronic device such that the entire battery board battery holder 130 is exposed from the housing of the electronic device. The length of these cables may be a length that allows the battery board 120 to be pulled out from the housing of the electronic device such that the entire battery board 120 is exposed from the housing of the electronic device.

The battery board 120 is disposed in the housing of the electronic device such that the battery board battery holder 130 in which the button-type battery is disposed is disposed inside the housing of the electronic device, and the battery board 120 can be inserted and removed from the outside of the housing of the electronic device through an insertion/removal port. The dummy battery unit 110 is attached to a circuit board battery holder that is a battery holder of a circuit board of the electronic device on which the battery board 120 is disposed. As a result, power is supplied from the button-type battery arranged in the battery board battery holder 130 to the circuit board of the electronic device via the circuit board battery holder. When the button-type battery arranged in the battery board battery holder 130 is exchanged, the battery board 120 is pulled out from the outside of the housing of the electronic device through the insertion/removal port. A state in which at least a part of the battery board 120 is pulled out from the insertion/removal port and in which the button-type battery arranged in the battery board battery holder 130 is exchangeable is referred to as an exchangeable state. The exchangeable state may be predetermined, for example, experimentally. In the exchangeable state, a state in which the ratio of the portion pulled out from the insertion/removal port to the entire battery board 120 is the smallest is referred to as a minimum exchangeable state. The minimum exchangeable state is a state in which the battery board 120 is pulled out from the insertion/removal port until a state of a portion exposed from the insertion/removal port of the battery board battery holder 130 becomes a state determined in advance as a state in which the button-type battery arranged in the battery board battery holder 130 can be exchanged.

The length of the cable connecting the negative electrode 111 and the negative terminal 131 and the length of the cable connecting the positive electrode 112 and the positive terminal 132 are lengths with which the battery board 120 can be pulled out from the insertion/removal port until the minimum exchangeable state is reached in a state where the dummy battery unit 110 is attached to the circuit board battery holder. Such a length of the cable connecting the positive electrode 112 and the positive terminal 132 is equal to or longer than a distance between the positive electrode 112 and the positive terminal 132 when the battery board 120 is pulled out from the insertion/removal port until the minimum exchangeable state is obtained. Such a length of the cable connecting the negative electrode 111 and the negative terminal 131 is equal to or longer than a distance between the negative electrode 111 and the negative terminal 131 when the battery board 120 is pulled out from the insertion/removal port until the minimum exchangeable state is obtained. In general, the cable connecting the positive electrode 112 and the positive terminal 132 and the cable connecting the negative electrode 111 and the negative terminal 131 are often coated and bonded as one cable except for the end portion. It is assumed that the cable connecting the positive electrode 112 and the positive terminal 132 and the cable connecting the negative electrode 111 and the negative terminal 131 having the same length are bonded as one cable except for the end portion. In this case, the length of these two cables is equal to or longer than the larger one of the length between the positive electrode 112 and the positive terminal 132 and the length between the negative electrode 111 and the negative terminal 131 when the battery board 120 is pulled out from the insertion/removal port until the battery board is in the minimum exchangeable state.

At least a part of the battery board battery holder 130 is exposed from the housing of the electronic device specifically means that at least a part of the battery board battery holder 130 is exposed from the insertion/removal port which is an opening formed in the housing of the electronic device. The size of the insertion/removal port is a size with which at least a part of the battery board battery holder 130 can be pulled out from the opening. In other words, the above-described length of the cable is a length that allows the battery board 120 to be pulled out from the insertion/removal port formed in the housing of the electronic device such that at least a part of the battery board battery holder 130 is exposed from the housing of the electronic device. As described above, the insertion/removal port is an opening formed on a housing of the electronic device. The insertion/removal port may be formed in the housing itself of the electronic device. The insertion/removal port may be formed in a component attached to the housing of the electronic device. The component attached to the housing of the electronic device is, for example, a bracket of an extension board attached to the electronic device.

### Effects

The present example embodiment has an effect that a system that enables exchange of a coin battery without opening a housing of an electronic device can suppress an area used on a surface of the housing.

This is because the dummy battery unit 110 includes the positive electrode 112 and the negative electrode 111 that can be attached to a circuit board battery holder that is a battery holder for a button-type battery of a circuit board of an electronic device. This is because the battery board 120 includes the battery board battery holder 130 which is a battery holder for a button-type battery including the positive terminal 132 connected to the positive electrode 112 and the negative terminal 131 connected to the negative electrode. Further, this is because the battery board 120 is disposed in the electronic device so as to be insertable to and removable from the outside of the housing of the electronic device.

### Second Example Embodiment

Next, the second example embodiment of the present disclosure will be described in detail with reference to the drawings.

### <Configuration>

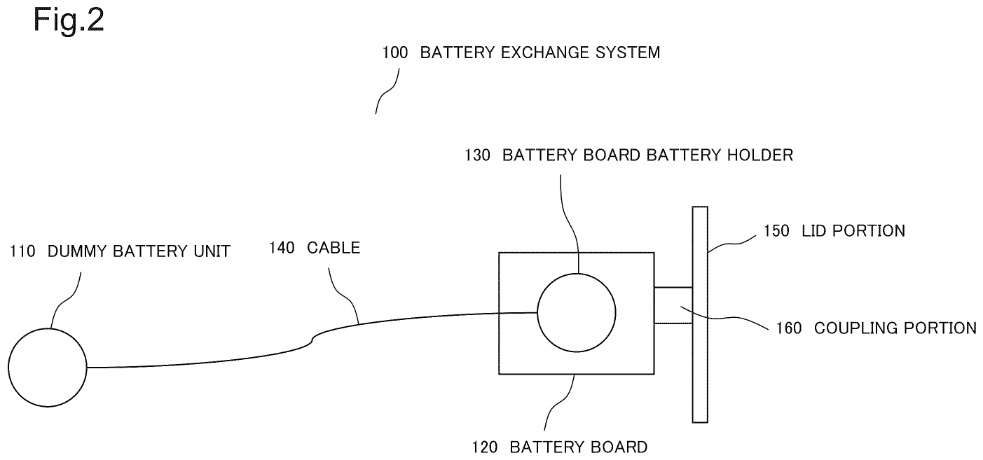

FIG. 2 is a diagram illustrating an example of a configuration of a battery exchange system according to the present disclosure.

Hereinafter, a configuration of a battery exchange system according to a second example embodiment of the present disclosure will be described in detail with reference to FIG. 2.

In the example illustrated in FIG. 2, a battery exchange system 100 of the present example embodiment includes a dummy battery unit 110, a battery board 120, a battery board battery holder 130, a cable 140, a lid portion 150, and a coupling portion 160.

The dummy battery unit 110 is the same as the dummy battery unit 110 of the first example embodiment.

The battery board 120 is the same as the battery board 120 of the first example embodiment except that the coupling portion 160 is connected to the battery board 120.

The battery board battery holder 130 is the same as the battery board battery holder 130 of the first example embodiment. The battery board battery holder 130 may be attached to the battery board 120 such that the flat surface of the button-type battery arranged in the battery board battery holder is parallel to the battery board 120. The flat surface of the button-type battery is, for example, a portion of a flat surface present on the negative electrode of the button-type battery.

The cable 140 connects the dummy battery unit 110 and the battery board battery holder 130 attached to the battery board 120. The cable 140 is relevant to the cable connecting the negative electrode 111 and the negative terminal 131 and the cable connecting the positive electrode 112 and the positive terminal 132 of the first example embodiment.

The configuration of the battery exchange system 100 according to the present example embodiment is a configuration in which the lid portion 150 and the coupling portion 160 are added to the configuration of the battery exchange system 10 of the first example embodiment. As described above, the shapes of the members (for example, the battery board 120, the battery board battery holder 130, the lid portion 150, the coupling portion 160, and the like) illustrated in FIG. 2 and other drawings may be different from the shapes of these members illustrated in FIG. 2 and other drawings.

The lid portion 150 is a member that functions as a lid of an insertion/removal port for the battery board 120 formed in the housing of the electronic device when the battery board 120 is inserted into the housing of the electronic device. As described above, the battery board 120 is disposed in the electronic device so as to be insertable to and removable from the outside of the housing of the electronic device. The battery board 120 is disposed in the electronic device so as to be insertable to and removable from the outside of the housing of the electronic device through the above-described insertion/removal port.

The coupling portion 160 is a member coupled to the battery board 120 and the lid portion 150. The coupling portion 160 couples the battery board 120 and the lid portion 150. The coupling portion 160 may be bonded to the battery board 120. The coupling portion 160 may be coupled to the battery board 120 by a screw or the like. The coupling portion 160 may be fixed to the battery board 120 by fitting. The coupling portion 160 may be formed integrally with the battery board 120. The coupling portion 160 may be bonded to the lid portion 150. The coupling portion 160 may be connected to the lid portion 150 by a screw or the like. The coupling portion 160 may be fixed to the battery board 120 by fitting. The coupling portion 160 may be formed integrally with the lid portion 150.

As described above, the size of the insertion/removal port is such that the battery board 120 including the battery board battery holder 130 can be pulled out from the insertion/removal port.

### Effects

The present example embodiment has the effect same as that of the first example embodiment. The reason is the same as the reason why the effect of the first example embodiment occurs.

### Third Example Embodiment

Next, a battery exchange system according to the third example embodiment of the present disclosure will be described in detail with reference to drawings.

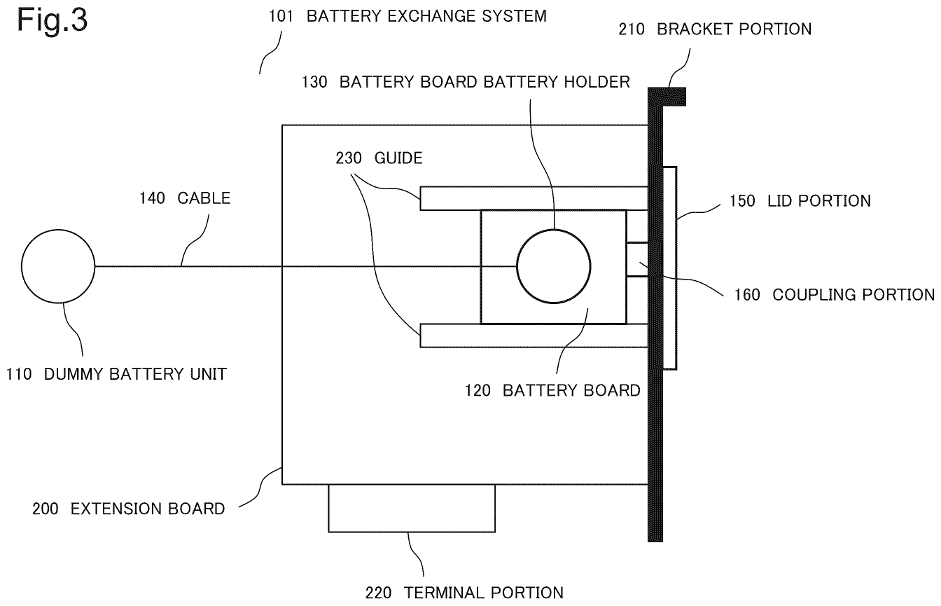

FIG. 3 is a diagram schematically illustrating an example of a configuration of a battery exchange system according to the present disclosure.

Hereinafter, a battery exchange system according to the third example embodiment of the present disclosure will be described in detail with reference to FIG. 3.

In the example illustrated in FIG. 3, a battery exchange system 101 includes a dummy battery unit 110, a battery board 120, a battery board battery holder 130 attached to the battery board 120, a cable 140, a lid portion 150, a coupling portion 160, and an extension board 200.

The extension board 200 includes a bracket portion 210, a terminal portion 220, and a guide 230.

The dummy battery unit 110, the battery board 120, the battery board battery holder 130, the cable 140, the lid portion 150, and the coupling portion 160 are the same as the dummy battery unit 110, the battery board 120, the battery board battery holder 130, the cable 140, the lid portion 150, and the coupling portion 160 of the second example embodiment.

The extension board 200 is an extension board that has a shape conforming to a predetermined standard and is attachable to a slot for an extension board of an electronic device. The predetermined standard is, for example, Peripheral Component Interconnect Express (PCIe, registered trademark). PCIe is also referred to as PCI-E. As described above, the shapes of the members (for example, the bracket portion 210, the terminal portion 220, the guide 230, and the like) of the extension board 200 and the extension board 200 depicted in FIG. 3 and other drawings may be different from the shapes of these members depicted in FIG. 3 and other drawings.

The guide 230 is, for example, a member that supports the battery board 120 so that the battery board 120 moves in a predetermined direction with reference to the extension board 200. This predetermined direction may be a direction parallel to the board surface of the extension board 200. The board surface of the extension board 200 is a surface of the board of the extension board 200. In the following description, the board surface is also referred to as a flat surface. The battery board 120 is mounted on the board surface of the extension board 200. The board surface of the extension board 200 is a surface including a vertical straight line and a horizontal straight line in the example illustrated in FIG. 3. This predetermined direction is a direction in which the battery board 120 moves when the battery board 120 is inserted and removed from the insertion/removal port. In other words, the guide 230 limits the direction in which the battery board 120 moves to the above-described predetermined direction. Specifically, the guide 230 limits the direction in which the battery board 120 moves so that the battery board 120 moves in a direction parallel to the board surface (that is, the flat surface) of the battery board 120 when the battery board 120 is inserted and removed from the outside of the electronic device on which the extension board is mounted. Thus, when the extension board 200 is incorporated in the electronic device, the battery board 120 is disposed in the housing of the electronic device so as to be insertable to and removable from the outside in a direction parallel to the flat surface of the battery board 120.

The terminal portion 220 is a member having a shape that can be inserted into the connector of the slot of the extension board. In the present example embodiment, the terminal portion 220 may not include a terminal.

The bracket portion 210 functions as a bracket of the extension board 200. When the extension board 200 is attached to the electronic device, at least a part of the bracket portion 210 is exposed to the outside of the electronic device. When the extension board 200 is attached to the electronic device, at least a part of the bracket portion 210 exposed to the outside of the electronic device functions as a part of the housing of the electronic device. The insertion/removal port described above is formed in the bracket portion 210. Specifically, the insertion/removal port is formed in at least a part of the bracket portion 210 exposed to the outside of the electronic device when the extension board 200 is attached to the electronic device. The battery board 120 is attached to the extension board 200 so as to be insertable to and removable from the insertion/removal port of the bracket portion 210.

The lid portion 150 may be formed so as to close the insertion/removal port formed in the bracket portion 210. The lid portion 150 may be formed so as to close a part of the insertion/removal port formed in the bracket portion 210.

A mechanism for fixing the lid portion 150 to the bracket portion 210 may be formed in the lid portion 150 and the bracket portion 210. The mechanism for fixing the lid portion 150 to the bracket portion 210 may be, for example, a screw and a screw hole.

The mechanism for fixing the lid portion 150 to the bracket portion 210 may be, for example, a mechanism for switching a state between the lid portion 150 and the bracket portion 210 between a state in which the lid portion 150 and the bracket portion 210 are fixed and a state in which the lid portion 150 and the bracket portion 210 are not fixed. Such a mechanism may be achieved by, for example, a member that is attached to the lid portion 150 and fixes the lid portion 150 to the bracket portion 210. This member is, for example, a member configured to be switched between a fixed state in which the lid portion 150 and the member thereof are sandwiched by the bracket portion 210 and a released state in which the lid portion 150 and the member thereof are not sandwiched by the bracket portion 210. The fixed state in this case is, for example, a state in which the battery board 120 cannot be removed from the electronic device due to the bracket portion 210 sandwiching the lid portion 150 and the member thereof. The released state in this case is, for example, a state in which the battery board 120 can be removed from the electronic device since the lid portion 150 and the member thereof are not sandwiched by the bracket portion 210. The switching between the fixed state and the released state may be performed, for example, by changing at least one of the relative position and the posture of the member with respect to the lid portion 150. At least one of the relative position and the posture of the member with respect to the lid portion 150 may be changed by sliding or rotating the member with respect to the lid portion 150.

The mechanism for fixing the lid portion 150 to the bracket portion 210 may be achieved by, for example, a member having at least one of flexibility and elasticity and formed on the lid portion 150. This member is formed to include a protrusion. When the battery board 120 is inserted and removed from the insertion/removal port, the position of the protrusion changes between a state where the protrusion is outside the housing of the electronic device and a state where the protrusion is inside the housing of the electronic device. For example, when the battery board 120 is pulled out from the insertion/removal port, the position of the protrusion is in a state where the protrusion is outside the housing of the electronic device. For example, when the battery board 120 is inserted into the electronic device until the lid portion 150 comes into contact with the bracket portion 210, the position of the protrusion is in a state where the protrusion is inside the housing of the electronic device. When the position of the protrusion changes between these two states, the protrusion passes through the insertion/removal port. The member is formed such that the protrusion passes through the insertion/removal port by bending of the member when the protrusion passes through the insertion/removal port. When the battery board 120 is inserted into the electronic device until the lid portion 150 comes into contact with the bracket portion 210, the protrusion of this member is formed such that the bracket portion 210 is sandwiched between the protrusion and the lid portion 150.

The mechanism for fixing the lid portion 150 to the bracket portion 210 may be achieved by, for example, a member formed on the lid portion 150 which comes into contact with the insertion/removal port when the battery board 120 is inserted into the electronic device until the lid portion 150 comes into contact with the bracket portion 210. This member may be formed such that when the battery board 120 is inserted into the electronic device until the lid portion 150 comes into contact with the bracket portion 210, the lid portion 150 is fixed to the bracket portion 210 by contact friction between the edge of the insertion/removal port and this member.

Hereinafter, a case where the mechanism for fixing the lid portion 150 to the bracket portion 210 is, for example, a screw and a screw hole will be further described.

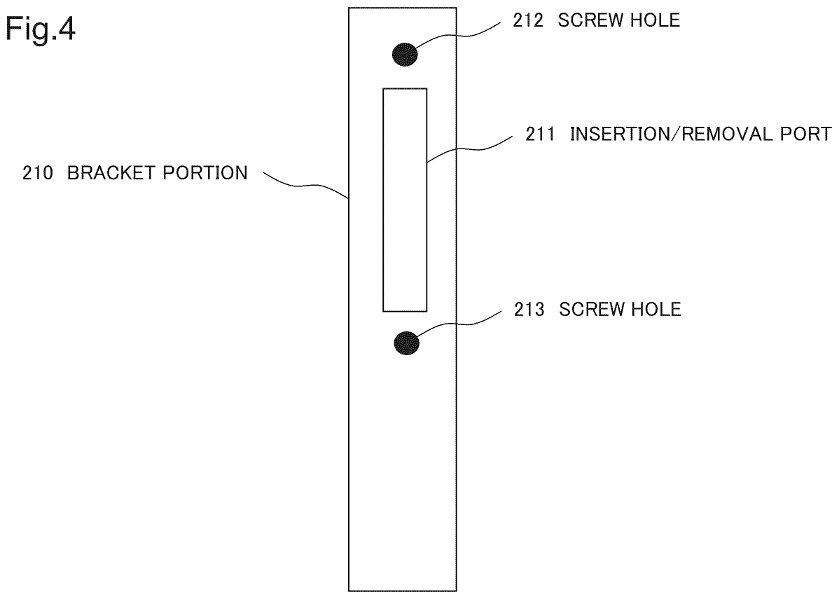

FIG. 4 is a diagram schematically illustrating an example of the bracket portion 210 of the extension board according to the present disclosure. The example illustrated in FIG. 4 represents the bracket portion 210 as viewed from the right direction in FIG. 3. In FIG. 4, the battery board 120 is pulled out from the extension board 200.

In the example of FIG. 4, an insertion/removal port 211, a screw hole 212, and a screw hole 213 are formed in the bracket portion 210. The arrangement and shapes of the bracket portion 210, the insertion/removal port 211, the screw hole 212, and the screw hole 213 may be different from the arrangement and shapes of the bracket portion 210, the insertion/removal port 211, the screw hole 212, and the screw hole 213 illustrated in FIG. 4.

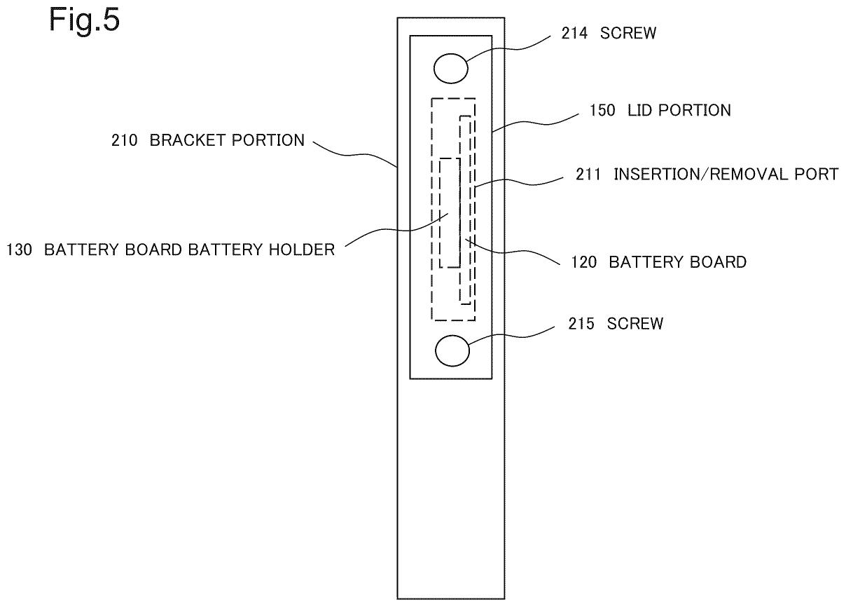

FIG. 5 is a diagram schematically illustrating an example of a bracket portion and a lid portion of the extension board according to the present disclosure. The example illustrated in FIG. 5 represents the bracket portion 210 and the lid portion 150 when viewed from the right direction of FIG. 3. In FIG. 5, the battery board 120 is inserted into the insertion/removal port 211 of the extension board 200.

In the example of FIG. 5, the bracket portion 210 and the lid portion 150 are fixed to each other by a screw 214 and a screw 215. The screw 214 is fixed to the screw hole 212 of FIG. 4. The screw 215 is fixed to the screw hole 213 of FIG. 4. The insertion/removal port 211 is closed by the lid portion 150. In the example of FIG. 5, the thickness of the battery board 120, including the thickness of the battery board battery holder 130, of the battery board 120 to which the battery board battery holder 130 is attached is smaller than the width of the insertion/removal port 211. The shapes of the bracket portion 210, the lid portion 150, the screw 214, the screw 215, the insertion/removal port 211, the battery board 120, and the battery board battery holder 130 may be different from the shapes drawn in FIG. 5.

### Effects

The present example embodiment has the effect same as that of the first example embodiment. The reason is the same as the reason why the effect of the first example embodiment occurs.

### Fourth Example Embodiment

Next, a fourth example embodiment of the present disclosure will be described in detail with reference to the drawings.

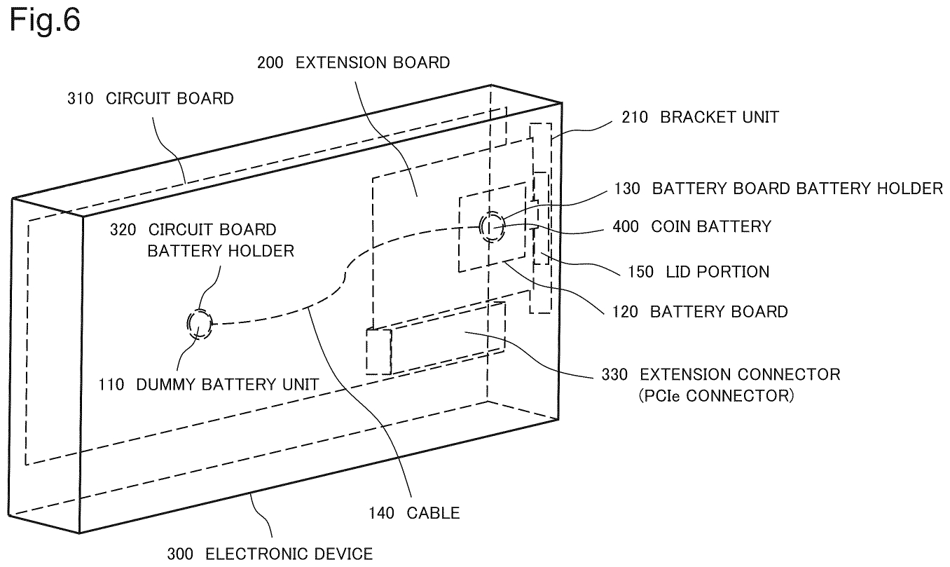

FIG. 6 is a diagram schematically illustrating an example of a configuration of an electronic device according to the present disclosure.

Hereinafter, a configuration of the electronic device according to the fourth example embodiment of the present disclosure will be described in detail with reference to FIG. 6.

In the example illustrated in FIG. 6, an electronic device 300 includes a circuit board 310 and a battery exchange system 101. In this example, the battery exchange system 101 illustrated in FIG. 3 is incorporated in the electronic device 300. The electronic device 300 is, for example, a blade-type server (also referred to as a blade server) which is a server device of a blade type. The circuit board 310 is, for example, a main board (in other words, a mother board) of the electronic device 300. On the circuit board 310, devices for the electronic device 300 to operate as a computer, such as a processor, a memory, and an interface control chip, are mounted. Shapes and arrangements of the electronic device 300, the circuit board 310, a circuit board battery holder 320, and an extension connector 330 may be different from the shapes illustrated in FIG. 6. In FIG. 6, in order to simplify the drawing, devices other than the circuit board 310 included in the electronic device 300 and the device related to the battery exchange system are not illustrated. However, the electronic device 300 may further include a device (for example, a storage device or the like) not illustrated in FIG. 6.

The circuit board 310 includes the circuit board battery holder 320 and the extension connector 330. The circuit board battery holder 320 is a battery holder on which a button-type battery can be mounted. The extension connector 330 is a connector in which an extension board of a predetermined standard can be added. The predetermined standard is, for example, PCIe. In this case, the extension connector 330 is also referred to as a PCIe connector.

The battery exchange system 101 includes a dummy battery unit 110, a battery board 120 to which the battery board battery holder 130 is attached, a cable 140 that connects the dummy battery unit 110 and the battery board battery holder 130, and an extension board 200. The extension board 200 is the same as the extension board 200 of the third example embodiment illustrated in FIG. 3. Each of the dummy battery unit 110, the battery board 120, the battery board battery holder 130, and the cable 140 are the same as the dummy battery unit 110, the battery board 120, the battery board battery holder 130, and the cable 140 according to the third example embodiment illustrated in FIG. 3.

The terminal portion 220 of the extension board 200 is inserted into the extension connector 330. The dummy battery unit 110 is inserted into the circuit board battery holder 320. A button-type battery 400 is mounted on the battery board battery holder 130. The button-type battery 400 is a button-type battery described above. As a result, the electric power of the button-type battery 400 can be used on the circuit board 310 of the electronic device 300.

By pulling the lid portion 150 connected to the battery board 120 by the coupling portion 160 and pushing the lid portion 150, the battery board 120 can be inserted and removed from an insertion/removal port formed in the bracket portion 210 functioning as a part of the housing of the electronic device 300.

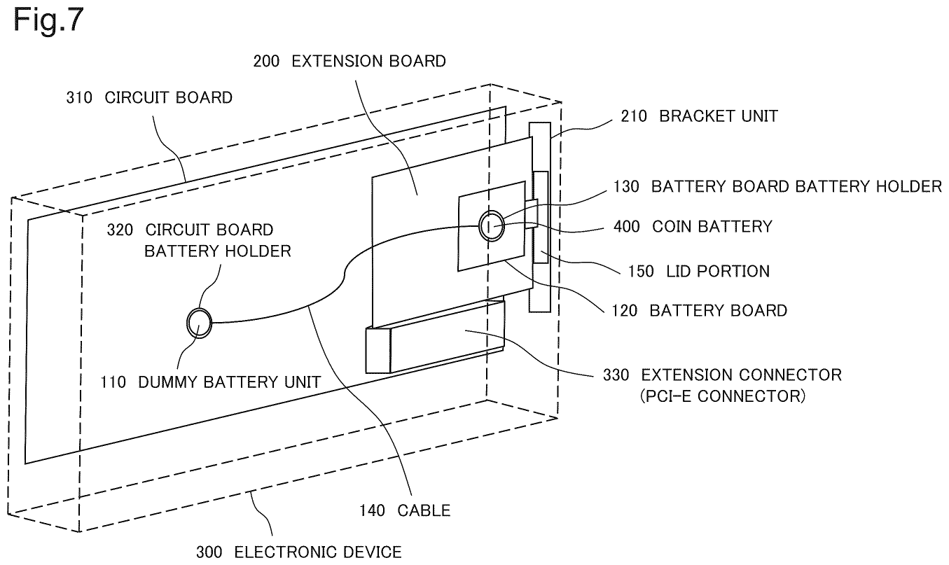

FIG. 7 is a diagram illustrating an inside of a housing of the electronic device according to the present disclosure. The example illustrated in FIG. 7 represents the inside of the housing of the electronic device 300 illustrated in FIG. 6.

### Effects

The present example embodiment has the effect same as that of the first example embodiment. The reason is the same as the reason why the effect of the first example embodiment occurs.

### Fifth Example Embodiment

Next, a fifth example embodiment of the present disclosure will be described in detail with reference to the drawings.

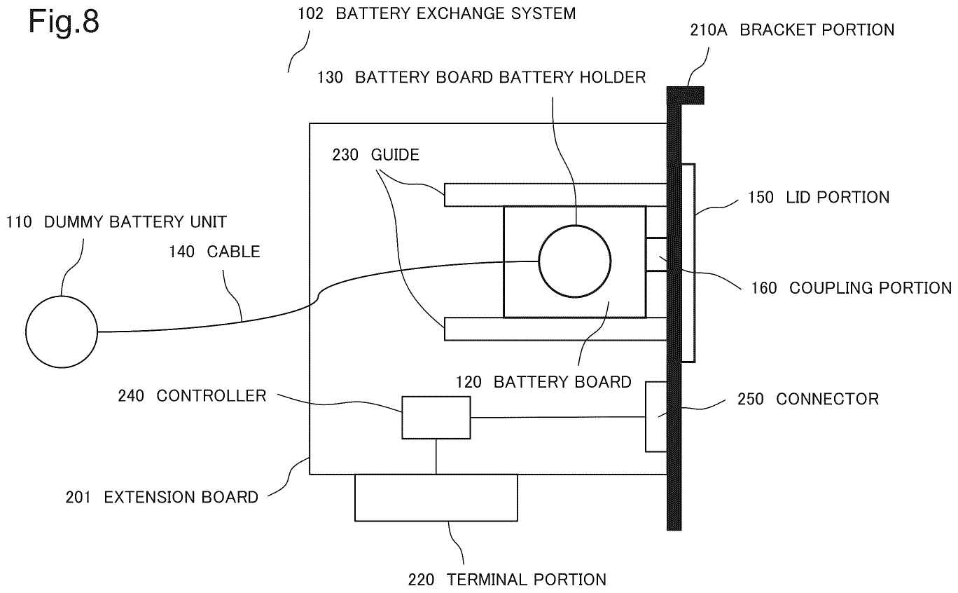

FIG. 8 is a diagram illustrating an example of a configuration of a battery exchange system according to the present disclosure.

Hereinafter, a configuration of a battery exchange system according to the fifth example embodiment of the present disclosure will be described in detail with reference to FIG. 8. In the example illustrated in FIG. 3, an extension board 201 provides a communication interface of a predetermined standard. The communication interface of the predetermined standard is, for example, a universal serial bus (USB, registered trademark). The USB standard may be any standard. The predetermined standard may not be the USB.

In the example illustrated in FIG. 8, a battery exchange system 102 of the present example embodiment includes a dummy battery unit 110, a battery board 120, a battery board battery holder 130, a cable 140, and an extension board 201.

The dummy battery unit 110, the battery board 120, the battery board battery holder 130, and the cable 140 are the same as the dummy battery unit 110, the battery board 120, the battery board battery holder 130, and the cable 140 of the third example embodiment illustrated in FIG. 3.

The extension board 201 includes a bracket portion 210A, a terminal portion 220, a guide 230, a controller 240, and a connector 250.

The controller 240 performs control to relay the above-described communication of the predetermined standard between the electronic device in which the battery exchange system 102 is incorporated and another device connected to the connector 250 via the terminal portion 220 and the connector 250. In a case where the above-described predetermined standard is USB, the connector 250 is a USB connector. In the present example embodiment, the terminal portion 220 includes a terminal conforming to the standard to which the extension board 201 conforms.

The battery exchange system 102 of the present example embodiment is the same as the battery exchange system 101 of the third example embodiment except that the extension board 201 is included instead of the extension board 200.

The extension board 201 is the same as the extension board 200 of the third example embodiment except that it includes the controller 240 and the connector 250, that it includes the bracket portion 210A instead of the bracket portion 210, and that it includes the terminal conforming to a standard with which the shape of the extension board 200 conforms. In the bracket portion 210A, a connector port, which is a hole for accessing the connector 250 from the opposite side of the connector 250 with respect to the bracket portion 210A, is formed. The terminal portion 220 of the extension board 200 may include a terminal. The terminal portion 220 of the extension board 200 may not include a terminal.

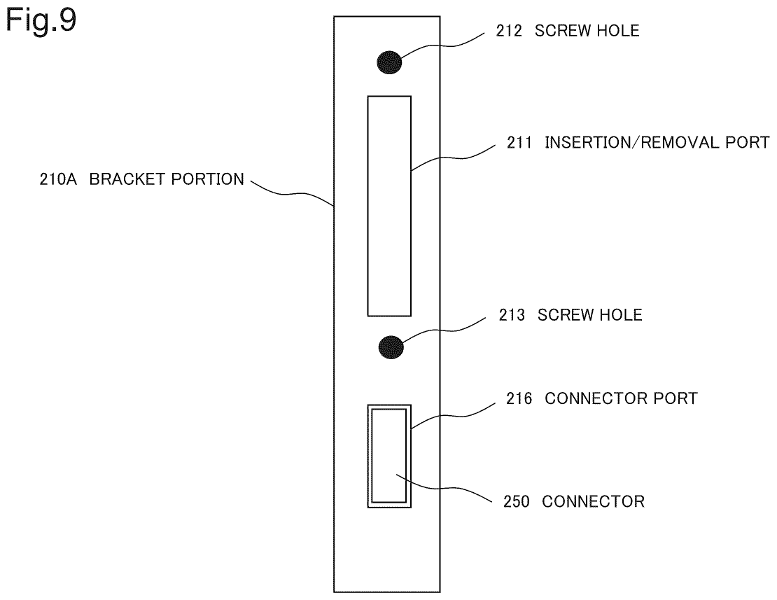

FIG. 9 is a diagram schematically illustrating an example of a bracket portion of the extension board according to the present disclosure. The example illustrated in FIG. 9 represents the bracket portion 210A as viewed from the right direction in FIG. 8. In FIG. 9, the battery board 120 is pulled out from the extension board 201.

In the example of FIG. 9, an insertion/removal port 211, a screw hole 212, a screw hole 213, and a connector port 216 are formed in the bracket portion 210A. The connector port 216 is the above-described connector port. The connector 250 can be accessed through the connector port 216. The arrangement and shape of the bracket portion 210A, the insertion/removal port 211, the screw hole 212, the screw hole 213, the connector port 216, and the connector 250 may be different from the arrangement and shape illustrated in FIG. 9.

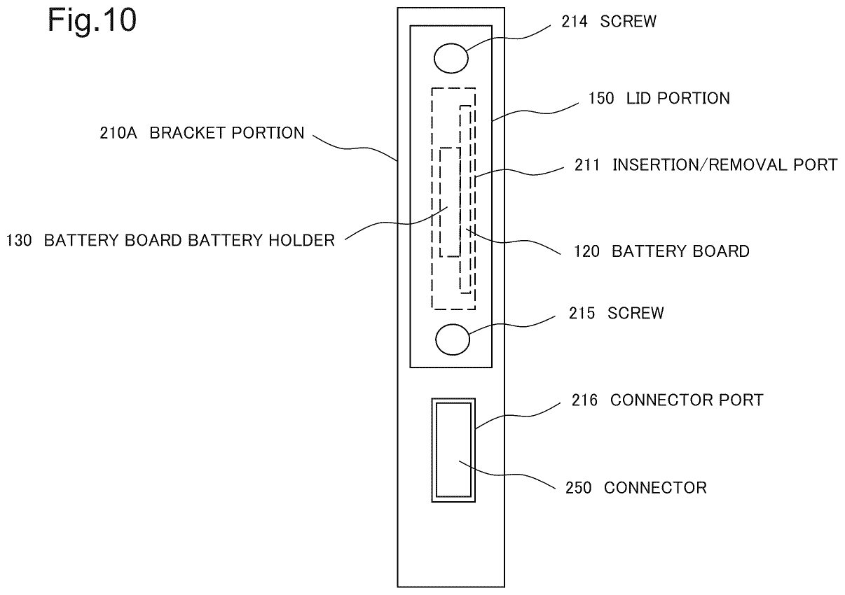

FIG. 10 is a diagram schematically illustrating an example of a bracket portion and a lid portion of the extension board according to the present disclosure. The example illustrated in FIG. 10 represents the bracket portion 210A and the lid portion 150 when viewed from the right direction of FIG. 8. In FIG. 9, the battery board 120 is inserted into the insertion/removal port 211 of the extension board 201.

In the example of FIG. 10, the bracket portion 210A and the lid portion 150 are fixed to each other by a screw 214 and a screw 215. The screw 214 is fixed to the screw hole 212 of FIG. 9. The screw 215 is fixed to the screw hole 213 of FIG. 9. The insertion/removal port 211 is closed by the lid portion 150. In the example of FIG. 10, the thickness of the battery board 120, including the thickness of the battery board battery holder 130, of the battery board 120 to which the battery board battery holder 130 is attached is smaller than the width of the insertion/removal port 211. The shapes of the bracket portion 210A, the lid portion 150, the screw 214, the screw 215, the insertion/removal port 211, the battery board 120, and the battery board battery holder 130 may be different from the shapes drawn in FIG. 10.

### Effects

The present example embodiment has the effect same as that of the first example embodiment. The reason is the same as the reason why the effect of the first example embodiment occurs.

### First Modification of Second Example Embodiment

Next, a first modification of the second example embodiment of the present disclosure will be described in detail with reference to the drawings.

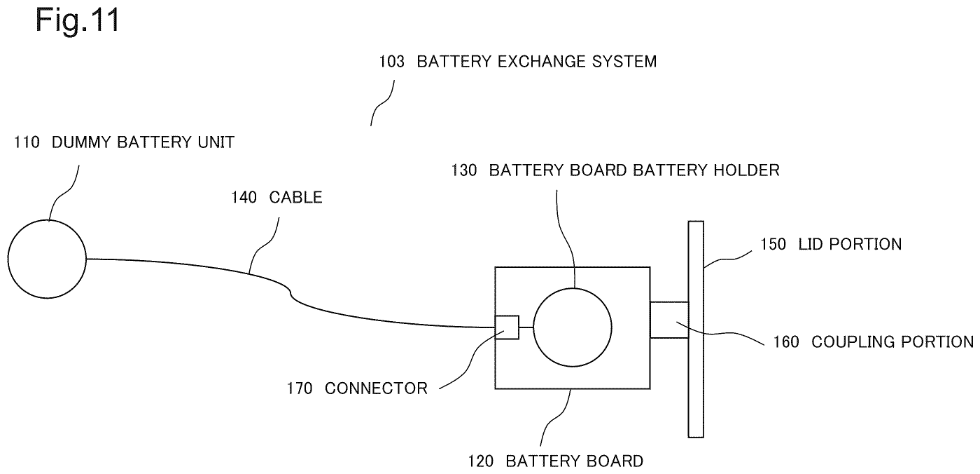

FIG. 11 is a diagram illustrating an example of a configuration of a battery exchange system according to the present disclosure.

Hereinafter, a battery exchange system 103 according to the first modification of the second example embodiment of the present disclosure will be described in detail with reference to FIG. 11.

In the battery exchange system 103 illustrated in FIG. 11, the dummy battery unit 110 is connected to the battery board battery holder 130 of the battery board 120 via the cable 140 and a connector 170. The battery exchange system 103 is the same as the battery exchange system 100 of the second example embodiment illustrated in FIG. 2 except that the dummy battery unit 110 and the battery board battery holder 130 of the battery board 120 are connected via the connector 170.

The connector 170 includes a connector on the battery board 120 side and a connector (in the example of FIG. 11, a connector connected to the cable 140) on the dummy battery unit 110 side. By connecting the connector on the battery board 120 side and the connector on the dummy battery unit 110 side, the dummy battery unit 110 and the battery board battery holder 130 are connected.

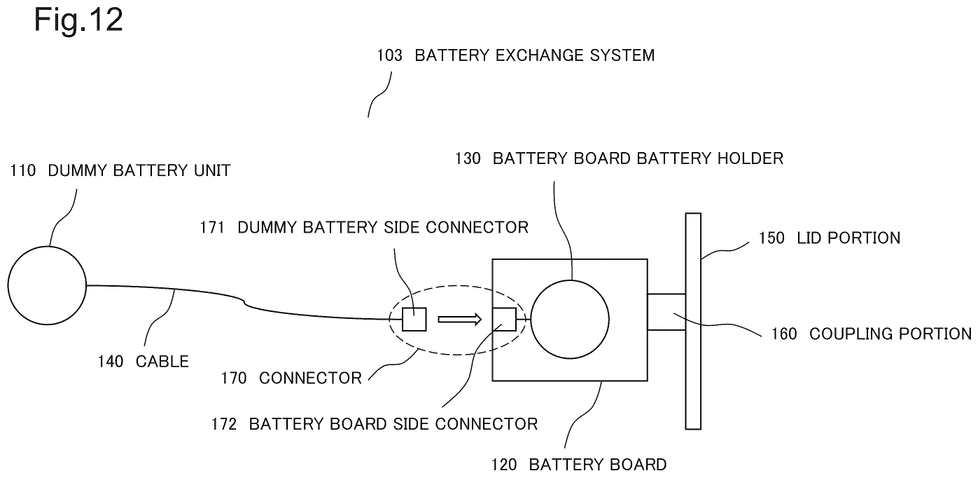

FIG. 12 is a second diagram illustrating an example of a configuration of the battery exchange system according to the present disclosure. FIG. 12 illustrates that a dummy battery side battery connector 171 and a battery board side connector 172 are connected.

The dummy battery side battery connector 171 is a connector on the dummy battery unit 110 side described above. The battery board side connector 172 is a connector on the battery board 120 side. The connector 170 includes the dummy battery side battery connector 171 and the battery board side connector 172.

### Second Modification of Second Example Embodiment

Next, a second modification of the second example embodiment of the present disclosure will be described in detail with reference to the drawings.

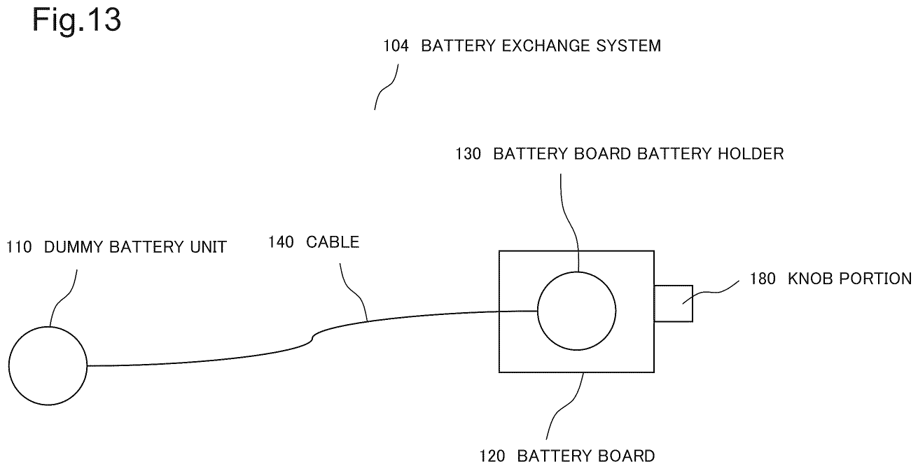

FIG. 13 is a diagram illustrating an example of a configuration of a battery exchange system according to the present disclosure.

Hereinafter, a battery exchange system 104 according to the second modification of the second example embodiment of the present disclosure will be described in detail with reference to FIG. 13.

The battery exchange system 104 illustrated in FIG. 13 is different from the battery exchange system 100 of the second example embodiment illustrated in FIG. 2 in that a knob portion 180 is included instead of the lid portion 150 and the coupling portion 160. The battery exchange system 104 is the same as the battery exchange system 100 of the second example embodiment illustrated in FIG. 2 except that the knob portion 180 is included instead of the lid portion 150 and the coupling portion 160.

The knob portion 180 is a member that can be picked by the knob when the battery board 120 is pulled out from the electronic device. Picking means holding in a pinched state. The knob portion 180 of the present modification is, for example, a member attached to the battery board 120. The knob portion 180 of the present modification may be, for example, a member formed on the battery board 120 and protruding from the battery board 120 in a direction parallel to the board surface of the battery board 120.

### Third Modification of Second Example Embodiment

Next, a third modification of the second example embodiment of the present disclosure will be described in detail with reference to the drawings.

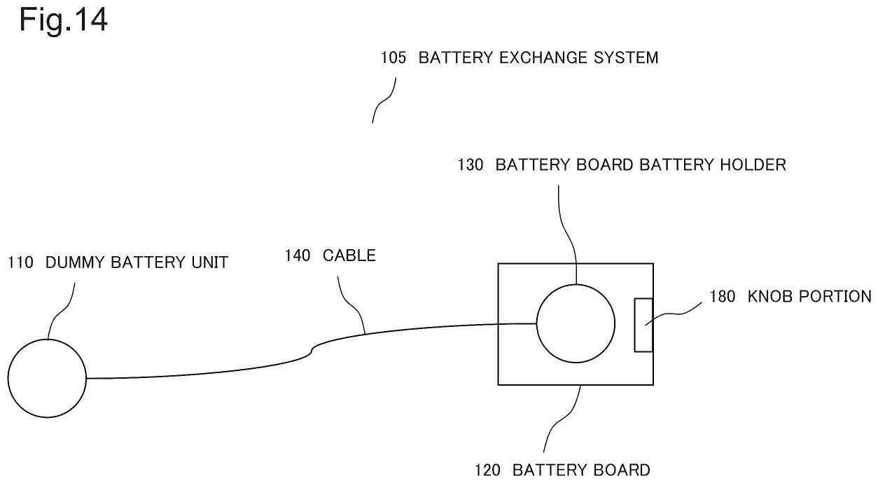

FIG. 14 is a diagram illustrating an example of a configuration of a battery exchange system according to the present disclosure.

Hereinafter, a battery exchange system 105 according to the third modification of the second example embodiment of the present disclosure will be described in detail with reference to FIG. 14.

The battery exchange system 105 illustrated in FIG. 14 is different from the battery exchange system 100 of the second example embodiment illustrated in FIG. 2 in that a knob portion 180 is included instead of the lid portion 150 and the coupling portion 160. The battery exchange system 105 is the same as the battery exchange system 100 of the second example embodiment illustrated in FIG. 2 except that the knob portion 180 is included instead of the lid portion 150 and the coupling portion 160.

The knob portion 180 is a member that can be picked by the knob when the battery board 120 is pulled out from the electronic device. The knob portion 180 of the present modification may be, for example, a member attached to the battery board 120 and having a convex shape in a direction perpendicular to the board surface of the battery board 120. The knob portion 180 of the present modification may be, for example, a member formed on the battery board 120 and having a convex shape in a direction perpendicular to the board surface of the battery board 120.

The knob portion 180 of the present modification may be, for example, a portion formed on the battery board 120 and having a concave shape in a direction perpendicular to the board surface of the battery board 120. In this case, the knob portion 180 is formed such that the thickness of the central portion of the knob portion 180 is smaller than the thickness of the right end portion of the knob portion 180 in FIG. 13.

### Fourth Modification of Second Example Embodiment

Next, a fourth modification of the second example embodiment of the present disclosure will be described in detail with reference to the drawings.

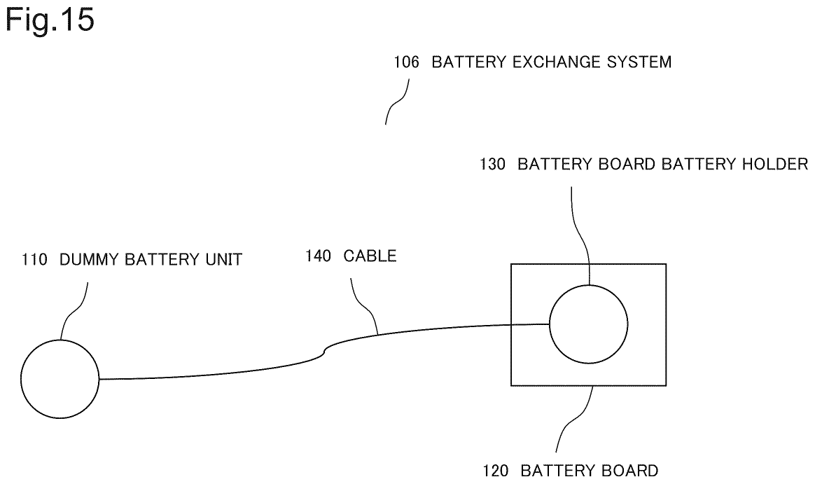

FIG. 15 is a diagram illustrating an example of a configuration of a battery exchange system according to the present disclosure.

Hereinafter, a battery exchange system 106 according to the fourth modification of the second example embodiment of the present disclosure will be described in detail with reference to FIG. 15.

The battery exchange system 105 illustrated in FIG. 15 is different from the battery exchange system 100 of the second example embodiment illustrated in FIG. 2 in that the lid portion 150 and the coupling portion 160 are not included. The configuration of the battery exchange system 105 is relevant to the configuration in which the two cables are represented as the cables 140 in the battery exchange system 10 of the first example embodiment illustrated in FIG. 1.

### First Modification of Fifth Example Embodiment

Next, a first modification of the fifth example embodiment of the present disclosure will be described in detail with reference to the drawings.

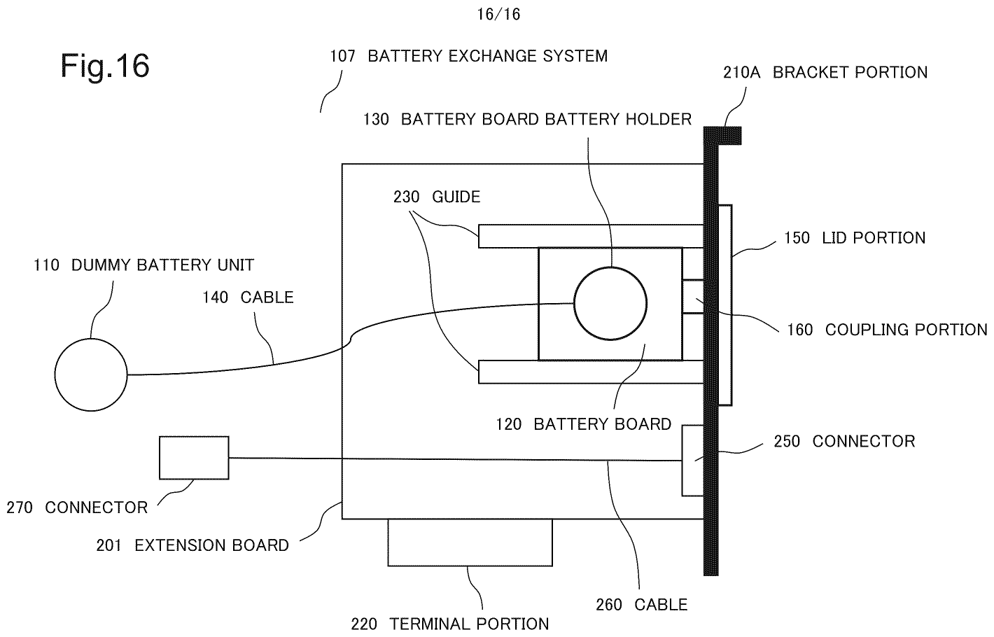

FIG. 16 is a diagram schematically illustrating an example of a battery exchange system according to the present disclosure.

Hereinafter, a battery exchange system according to the first modification of the fifth example embodiment of the present disclosure will be described in detail with reference to FIG. 14.

A battery exchange system 107 illustrated in FIG. 16 is different from the battery exchange system 102 of the second example embodiment illustrated in FIG. 8 in that a cable 260 and a connector 270 are included instead of the controller 240. The battery exchange system 107 is the same as the battery exchange system 102 of the fifth example embodiment illustrated in FIG. 8 except that it includes a cable 260 and a connector 270 instead of the controller 240. The connector 250 is connected to, for example, a device different from the electronic device. The connector 270 is connected to, for example, a connector mounted on a circuit board of an electronic device.

The connector 250 and the connector 270 are connected by the cable 260. The connector 250 and the connector 270 are connectors conforming to a predetermined standard of communication between the electronic device and a device connected to the connector 250. The cable 260 is a cable conforming to a predetermined standard. The predetermined standard may be, for example, a USB. The predetermined standard may be a standard other than the USB. In the present modification, the terminal portion 220 may not include a terminal.

### <Other Modifications>

The first modification of the second example embodiment, the second modification of the second example embodiment, the third modification of the second example embodiment, and the fourth modification of the second example embodiment can be applied to other example embodiments and other modifications.

The first modification of the fifth example embodiment can also be applied to the third example embodiment, the fourth example embodiment, and other modifications.

In addition, when any one of the second modification of the second example embodiment and the third modification of the second example embodiment is applied to at least any one of the third example embodiment, the fourth example embodiment, and the fifth example embodiment, a stopper may be formed in the guide 230.

As described above, the guide 230 is a member that restricts the movement of the battery board 120 in the direction along the guide 230. The stopper of the guide 230 is a member that is formed on the guide 230 and restricts the movement of the battery board 120. For example, the stopper limits the position of the battery board 120 to a position where the knob portion 180 can be picked from the bracket portion 210 or the outside of the bracket portion 210A. The bracket portion 210 or the outside of the bracket portion 210A refers to a side that becomes the outside of the electronic device with respect to the bracket portion 210 or the bracket portion 210A when the extension board 200 or the extension board 201 is incorporated in the electronic device. The position where the knob portion 180 can be picked from the outside of the bracket portion 210 or the bracket portion 210A may be a position determined in advance as a position where the knob portion 180 can be picked from the outside of the bracket portion 210 or the bracket portion 210A. In other words, the stopper is formed so as to stop the distal end of the battery board 120 inserted into the insertion/removal port 211 at a predetermined position in the direction along the guide 230. The distal end of the battery board 120 is a portion of the battery board 120 inserted into the insertion/removal port 211, the portion being inside the bracket portion (that is, the bracket portion 210 or the bracket portion 210A) and being farthest from the bracket portion. The inside of the bracket portion is a portion inside a housing of the electronic device when the extension board (the extension board 200 or the extension board 201) is incorporated in the electronic device.

In this case, the lid portion 150 that is not connected to battery board 120 may be attached to the bracket (that is, the bracket portion 210 or the bracket portion 210A).

The battery board 120 may not be attached to the extension board 200 or the like. In this case, the battery board 120 may be attached to the housing of the electronic device. The battery board 120 may be attached to, for example, a guide formed on the back side of one surface of the housing. The insertion/removal port may be formed on a surface of the housing of the electronic device different from the surface on which the guide is attached to the back so that the battery board 120 can be inserted and removed through the insertion/removal port.

In an electronic device such as a computer, for example, a coin-type battery is used for maintaining settings of a clock or a basic input output system (BIOS) stored in a complementary metal oxide semiconductor (CMOS). The coin-type battery is also called a coin battery, a coin-type battery, a button-type battery, or the like. In an electronic device such as a computer energized from an external power supply, the lifetime of a coin battery used is generally about five years. In order to use the computer or the like beyond the lifetime of the coin battery, it is necessary to exchange the coin battery. In general, in order to exchange a coin battery, it is necessary to open the housing of the electronic device and expose the holder of the coin battery. Therefore, it is necessary to stop the electronic device for a long time.

In the technique disclosed in JP 9-63555 A, it is possible to shorten the time for stopping the electronic device for exchanging the coin battery. However, in the technique of JP 9-63555 A, it is necessary to attach the second battery holder to the housing of the electronic device in a state where the entire second battery holder is exposed in a state where the lid covering the second battery holder is removed so that the coin battery can be exchanged. For example, it is difficult to provide the technique of JP 9-63555 A in a server device having a small area of a surface region that can be accessed from the outside in a state of being mounted on a rack, such as a blade-type server.

The present disclosure has an effect that a system that enables exchange of a coin battery without opening a housing of an electronic device can suppress an area used on a surface of the housing.

Some or all of the above example embodiments may be denoted as the following Supplementary Notes, but are not limited to the following.

### (Supplementary Note 1)

A battery exchange system including:
a dummy battery unit including a positive electrode and a negative electrode, the dummy battery unit being attachable to a circuit board battery holder that is a battery holder for a button-type battery, of a circuit board of an electronic device; and
a battery board including a battery board battery holder that is a battery holder for a button-type battery including a positive terminal connected to the positive electrode and a negative terminal connected to the negative electrode, the battery board being disposed in the electronic device so as to be insertable to and removable from an outside of a housing of the electronic device.

### (Supplementary Note 2)

The battery exchange system according to Supplementary Note 1, in which
the battery board is disposed in the electronic device so as to be insertable to and removable from the outside of the housing in a direction parallel to a flat surface of the battery board.

### (Supplementary Note 3)

The battery exchange system according to Supplementary Note 1 or 2, in which
the battery board battery holder is attached to the battery board in such a way that a flat surface of a button-type battery arranged in the battery board battery holder is parallel to the battery board.

### (Supplementary Note 4)

The battery exchange system according to Supplementary Note 1 or 2, in which
the battery board is attached to an extension board mountable on the electronic device so as to be insertable to and removable from an insertion/removal port formed in a bracket portion that is a portion exposed to an outside when the extension board is attached to the electronic device.

### (Supplementary Note 5)

The battery exchange system according to Supplementary Note 4, including a cable that conducts the positive electrode and the positive terminal and conducts the negative electrode and the negative terminal, in which a length of the cable is equal to or longer than a larger one of a length between the positive electrode and the positive terminal and a length between the negative electrode and the negative terminal when the battery board is pulled out from the insertion/removal port until a state of a portion exposed from the insertion/removal port of the battery board battery holder becomes a predetermined state.

### (Supplementary Note 6)

The battery exchange system according to Supplementary Note 4, further including a lid portion that is removable from the bracket portion of the extension board to an outside of the electronic device when the extension board is attached to the electronic device, and is attachable to the bracket portion so as to close at least a part of the insertion/removal port, the lid portion being fixed to the battery board.

### (Supplementary Note 7)

The battery exchange system according to Supplementary Note 4, in which
the extension board is a board having a shape mountable in a peripheral component interconnect express (PCIe) slot of the electronic device.

### (Supplementary Note 8)

The battery exchange system according to Supplementary Note 7, in which
in the extension board, a connector of a predetermined interface that can be used for communication from the electronic device via the PCIe slot is further formed in the bracket portion.

### (Supplementary Note 9)

The battery exchange system according to Supplementary Note 4, including:
the battery board; and the extension board.

### (Supplementary Note 10)

An electronic device including:
the extension board; and
the battery exchange system according to Supplementary Note 5.

### (Supplementary Note 11)

The battery exchange system according to Supplementary Note 1 or 2, in which
the electronic device is a blade-type server.

The previous description of embodiments is provided to enable a person skilled in the art to make and use the present disclosure. Moreover, various modifications to these example embodiments will be readily apparent to those skilled in the art, and the generic principles and specific examples defined herein may be applied to other embodiments without the use of inventive faculty. Therefore, the present disclosure is not intended to be limited to the example embodiments described herein but is to be accorded the widest scope as defined by the limitations of the claims and equivalents.

Further, it is noted that the inventor's intent is to retain all equivalents of the claimed invention even if the claims are amended during prosecution.

What is claimed is:

1. A battery exchange system comprising:
a dummy battery part including a positive electrode and a negative electrode, the dummy battery part being attachable to a circuit board battery holder of a circuit board of an electronic device, the circuit board battery holder being a battery holder for a button-type battery; and
a battery board including a battery board battery holder that is a battery holder for a button-type battery including a positive terminal connected to the positive electrode and a negative terminal connected to the negative electrode, the battery board being disposed in the electronic device so as to be insertable to and removable from an outside of a housing of the electronic device.

2. The battery exchange system according to claim 1, wherein
the battery board is disposed in the electronic device so as to be insertable to and removable from the outside of the housing in a direction parallel to a flat surface of the battery board.

3. The battery exchange system according to claim 1, wherein
the battery board battery holder is attached to the battery board in such a way that a flat surface of a button-type battery arranged in the battery board battery holder is parallel to the battery board.

4. The battery exchange system according to claim 1, wherein
the battery board is attached to an extension board mountable on the electronic device so as to be insertable to and removable from an insertion/removal port formed in a bracket portion that is a portion exposed to an outside in a case where the extension board is attached to the electronic device.

5. The battery exchange system according to claim 4, comprising
a cable that conducts the positive electrode and the positive terminal and conducts the negative electrode and the negative terminal, wherein
a length of the cable is equal to or longer than a larger one of a length between the positive electrode and the positive terminal and a length between the negative electrode and the negative terminal in a case where the battery board is pulled out from the insertion/removal port until a state of a portion exposed from the insertion/removal port of the battery board battery holder becomes a predetermined state.

6. The battery exchange system according to claim 4, further comprising a lid portion fixed to the battery board, the lid portion being removable from the bracket portion of the extension board to an outside of the electronic device in a case where the extension board is attached to the electronic device, the lid portion being attachable to the bracket portion so as to close at least a part of the insertion/removal port.

7. The battery exchange system according to claim 4, wherein
the extension board is a board having a shape mountable in a peripheral component interconnect express (PCIe) slot of the electronic device.

8. The battery exchange system according to claim 7, wherein
in the extension board, a connector of a predetermined interface that can be used for communication from the electronic device via the PCIe slot is further formed in the bracket portion.

9. The battery exchange system according to claim 4, comprising:
the battery board; and
the extension board.

10. The battery exchange system according to claim 1, wherein
the electronic device is a blade-type server.

11. An electronic device including the battery exchange system according to claim 5, the electronic device comprising
the extension board.
